(19) United States
(12) Patent Application Publication
(10) Pub. No.: US 2026/0118417 A1
(43) Pub. Date: Apr. 30, 2026

(54) INTEGRATED CIRCUIT TEST PLATFORM AND INTEGRATED CIRCUIT TEST SYSTEM WITH MATERIAL OVERLAP PREVENTION FUNCTION

(71) Applicant: CHROMA ATE INC., Taoyuan City (TW)

(72) Inventors: TZU-CHING YANG, Taoyuan City (TW); Ping-Hsun Lee, Taoyuan City (TW)

(21) Appl. No.: 19/230,318

(22) Filed: Jun. 6, 2025

(30) Foreign Application Priority Data
Oct. 30, 2024 (TW) 113141735

(51) Int. Cl. G01R 31/28

(52) U.S. Cl. CPC G01R 31/2891; G01R 31/2893

(57) ABSTRACT

An integrated circuit test platform includes a test head and a host. The integrated circuit test platform is for collaborating with a class handler. The test head is for the class handler to place or retrieve an object under test. The host is configured to perform a test procedure on the object under test by the test head, and providing a first command for the class handler to operate in a replacement stage. The replacement stage is for the class handler to first perform a retrieval procedure and then perform a placement procedure so as to complete replacement with another object under test. The host is for generating a second command for the class handler to cease operation when a residue test procedure is performed by the test head and there are residues of the object under test on the test head in the replacement stage.

### BACKGROUND OF THE INVENTION

### Field of the Invention

The present disclosure relates to an integrated circuit test platform and an integrated circuit test system, and more particularly to an integrated circuit test platform and an integrated circuit test system having a material overlap prevention function.

### Description of the Prior Art

An integrated circuit test system usually includes an integrated circuit test platform and a class handler or a prober. With the combination of an integrated circuit test platform and a class handler, an integrated circuit under test yet to undergo testing is placed in a test region of the integrated circuit test platform by the class handler, and after the integrated circuit test platform finishes the test procedure, the integrated circuit under test having undergone testing is classified and placed to a corresponding storage region by the class handler according to a test result, for example, classified as a qualified product or a defective product.

With the collaboration of the integrated circuit test platform, any limitations in terms of the quality and functions of the class handler itself are also closely associated with the stability of a test system. For example, some class handlers may experience errors during the transportation of an integrated circuit and may be unable to perform self-sensing due to the lack of related functions, for example, a class handler fails to correctly retrieve the integrated circuit under test from the integrated circuit test platform and continues operating. As a result, an occurrence of material overlap may be caused when another integrated circuit under test is subsequently placed, leading to damage of the integrated circuits under test. Therefore, it is imperative for a test system to improve and prevent the issues above.

### SUMMARY OF THE INVENTION

In some embodiments of the present disclosure, an integrated circuit test platform and an integrated circuit test system resolve the issue of material overlap potentially caused by a class handler, hence enhancing the reliability of the test system.

In some embodiments of the present disclosure, an integrated circuit test platform and an integrated circuit test system provide a function of detecting a material overlap condition without involving any additional testing time.

According to some embodiments, an integrated circuit test platform with a material overlap prevention function provided is for collaborating with a class handler to control a placement procedure and a retrieval procedure performed by the class handler. The integrated circuit test platform includes a test head and a host. The test head is configured to allow the class handler to place an object under test during the placement procedure, and retrieve the object under test during the retrieval procedure. The host is coupled to the test head and the class handler. The host is configured to perform a test procedure on the object under test by the test head, and providing a first command to the class handler to operate the class handler in a replacement stage. The replacement stage is for the class handler to first perform the retrieval procedure and then perform the placement procedure so as to complete replacement with another object under test. The host is for generating a second command for the class handler to cease operation when a residue test procedure is performed by the test head and there are residues of the object under test on the test head in the replacement stage.

According to some embodiments, an integrated circuit test system with a material overlap prevention function provided includes a class handler and the integrated circuit test platform above. The class handler is configured to perform the placement procedure or the retrieval procedure.

According to some embodiments, during a period of the residue test procedure performed by the host, the class handler configured to perform only the retrieval procedure of retrieving the object under test from the test head, or the placement procedure of placing another object under test.

According to some embodiments, the residue test procedure may be performed after the replacement stage has operated for a waiting time.

According to some embodiments, the residue test procedure may include a plurality of test loops configured to continuously and repeatedly perform inspection of whether there are residues of the object under test on the test head.

According to some embodiments, a total execution time for executing these test loops may be controlled to be less than a replacement time needed by the replacement stage minus the waiting time.

According to some embodiments, the host may be controlled to cease the residue test procedure upon receiving a third command generated by the class handler. The third command is generated when the class handler is about to complete the placement procedure of another object under test.

According to some embodiments, each of the test loops may be used for the host to perform an electrical measurement by the test head. The electrical measurement may be, for example, measurement of a resistance value of the object under test.

Accordingly, during a period of the residue test procedure performed in the replacement stage operated by the class handler, an inspection time that additionally increases the overall inspection process is not needed. That is, within a period of time that the class handler essentially consumes for replacing the object under test, on top of the characteristic of performing electrical testing on the object under test placed thereon, the test head is further used to perform the residue test procedure associated with electrical testing to inspect conditions on the test head. Thus, upon discovering any residues of the object under test, the second command may be sent timely to the class handler to cease operation of the class handler, so as to prevent another object under test from overlaying on the object under test remaining on the test head to thereby achieve a material overlap prevention function.

### BRIEF DESCRIPTION OF THE DRAWINGS

FIG. 1 is a functional block diagram of an integrated circuit test system with a material overlap prevention function according to some embodiments.

FIG. 2 is a schematic diagram of partial processes of an integrated circuit test platform with a material overlap prevention function according to some embodiments.

FIG. 3 is a schematic diagram of partial processes of a class handler of an integrated circuit test system with a material overlap prevention function according to some embodiments.

### DETAILED DESCRIPTION OF THE EMBODIMENTS

Objectives, features, and advantages of the present disclosure are hereunder illustrated with specific embodiments, depicted with drawings, and described below.

In the disclosure, descriptive terms such as “a” or “one” are used to describe the unit, component, structure, device, module, portion, section or region, and are for illustration purposes and providing generic meaning to the scope of the present invention. Therefore, unless otherwise explicitly specified, such description should be understood as including one or at least one, and a singular number also includes a plural number.

In the disclosure, descriptive terms such as “include, comprise, have” or other similar terms are not for merely limiting the essential elements listed in the disclosure, but can include other elements that are not explicitly listed and are however usually inherent in the units, components, structures, devices, modules, portions, sections or regions.

In the disclosure, the terms similar to ordinals such as “first” or “second” described are for distinguishing or referring to associated identical or similar components or structures, and do not necessarily imply the orders of these components, structures, portions, sections or regions in a spatial aspect. It should be understood that, in some situations or configurations, the ordinal terms could be interchangeably used without affecting the implementation of the present invention.

An integrated circuit test system usually includes an integrated circuit test platform, and a class handler for performing material placement and material retrieval and classifying an integrated circuit under test according to an inspection result provided by the integrated circuit test platform. Further, the integrated circuit test platform may include a test head for performing electrical testing, and a host for controlling the overall test process. The host may in general refer to components other than the test head in the integrated circuit test platform, for example, a device such as a computer.

The test head is a body for performing a test procedure for performing electrical testing on the integrated circuit under test, and various types of system test boards with respective dedicated functions are placed inside the test head to perform corresponding electrical test items. A test region for placing the integrated circuit under test is usually defined on the test head, for example but not limited to, a socket for testing. A fetching device of the class handler is for moving the integrated circuit under test to the test region on the test head, so that pins of the integrated circuit under test can come into contact with corresponding contacts of the test head to achieve electrical connection. The fetching device of the class handler is, for example but not limited to, a mechanical arm, a device consisting of the air pressure control technology and a suction nozzle, or other devices.

In some embodiments, when the class handler performs a placement procedure for placing the integrated circuit under test on the test head, a certain level of downward pressure may be continually provided on the integrated circuit under test after the placement procedure is complete, so as to ensure secure electrical connection between the integrated circuit under test and the test head until the test head completes the test procedure. On the other hand, for some integrated circuits under test, the class handler may simply perform the placement procedure to place the integrated circuits under test on the test head without additionally providing the downward pressure on the integrated circuits under test.

In some other embodiments, in addition to performing a placement procedure of placing an integrated circuit under test on the test head and performing a retrieval procedure of retrieving and classifying an integrated circuit under test from the test head to a corresponding storage region, the class handler may further provide, by another component (such as a contact pusher), an independent pressurization procedure of providing an integrated circuit under test with a certain level of downward pressure.

Once the test head completes testing of the integrated circuit under test, the class handler operates in a replacement stage. During the replacement stage, the class handler retrieves the integrated circuit under test having undergone complete testing from the test head, and replaces the same with another integrated circuit under test that has not tested yet. This replacement stage does not include the pressurization procedure described above. That is to say, it is ideal to minimize the time essentially consumed by the replacement stage.

On the other hand, some class handlers, due to cost considerations, do not include complex fetching devices and do not have any anomaly detection functions. Such class handler usually has one fetching device dedicated for retrieving or placing an integrated circuit under test; that is to say, when the class handler operates in the replacement stage, the fetching device is operable to perform only one of the following operations: currently retrieving an integrated circuit under test, currently placing an integrated circuit under test, and currently moving an integrated circuit under test. The operations of currently retrieving an integrated circuit under test and currently placing an integrated circuit under test include retrieval from or placement onto the test head, and include retrieval from and placement to an unclassified storage region (not yet tested) and a classified storage region (having been tested). These class handlers may be subject to occurrences of integrated circuit under test remaining on the test head due to certain reasons. However, in the event of such occurrences, the class handlers are unaware of such occurrences and continually perform the various steps of the replacement stage.

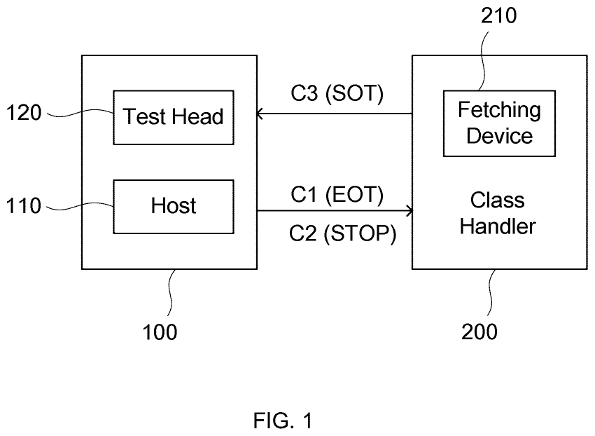

Refer to FIG. 1 showing a functional block diagram of an integrated circuit test system with a material overlap prevention function according to some embodiments. The integrated circuit test system with a material overlap prevention function includes a class handler 200 and an integrated circuit test platform 100. The class handler 200 performs a placement procedure or a retrieval procedure by a fetching device 210. The integrated circuit test platform 100 is for collaborating with the class handler 200 to control the placement procedure and the retrieval procedure performed by the class handler 200.

The integrated circuit test platform 100 includes a host 110 and a test head 120. When the placement procedure is complete and an object under test is placed on the test head 120, the class handler 200 provides a third comment C3 (Start-of-Test (SOT)) to the host 110 of the integrated circuit test platform 100, for the host 110 to prompt the test head 120 to start to perform a test procedure, thereby performing various types of electrical testing (including, for example but not limited to, electrical characteristics testing and power-on testing under predetermined temperature conditions) on the object under test.

Once the execution of the test procedure is complete, the host 110 provides a first command C1 (End-of-Test (EOT)) to the class handler 200 to prompt the class handler 200 to operate in a replacement stage, such that the class handler 200 sequentially performs the retrieval procedure and the placement procedure to further complete replacement with a next object under test. The first command C1 (EOT) may include information associated with a storage region corresponding to an inspection result of the object under test, for the class handler 200 to retrieve, classify and place the object under test having undergone testing to the corresponding storage region in the retrieval procedure in the replacement stage.

In this embodiment, during the replacement stage, the host 110 additionally performs a residue test procedure by the test head 120. The test head 120 performs an electrical measurement by one of the various types of electrical testing originally performed, or the test head 120 performs an electrical measurement by at least one electrical loop (at least one electrical loop constructed by pins of the object under test essentially coming into contact with the test head 120), for example, measuring a resistance value or a current value. When the test head 120 obtains a non-zero electrical value of the electrical loop, it means that there are residues of the object under test on the test head 120 (and this means that the execution of the retrieval procedure of the class handler 200 has failed). In this case, the host 110 provides a second command C2 (STOP) to the class handler 200 to cease the operation of the class handler 200, further preventing the class handler 200 from completing the execution of the placement procedure and hence from material overlap. Such material overlap between two objects under test overlapping each other causes breakage and damage.

Thus, the integrated circuit test platform 100 is able to simultaneously perform the residue test procedure while the class handler 200 operates in a time period of the replacement stage (replacing the object under test), further achieving the function of material overlap prevention without increasing the overall testing time.

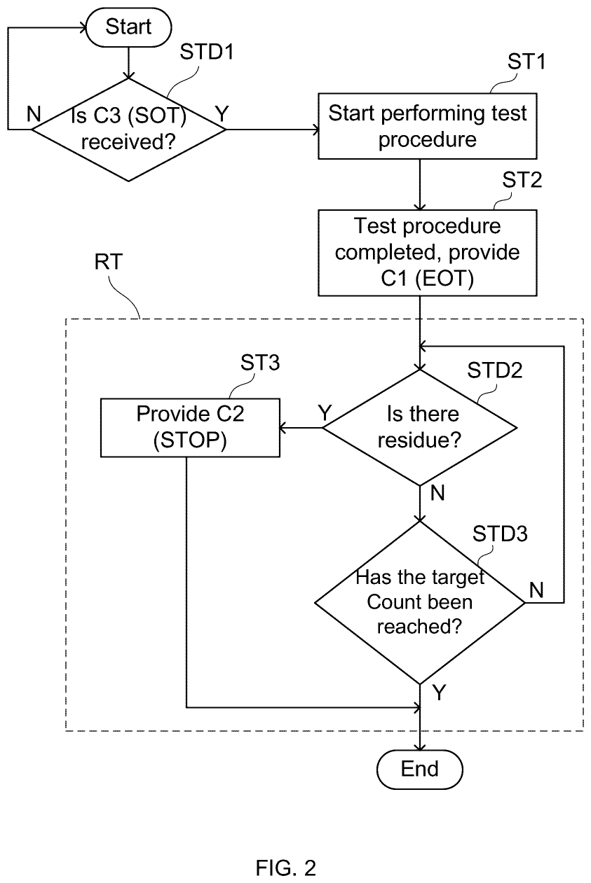

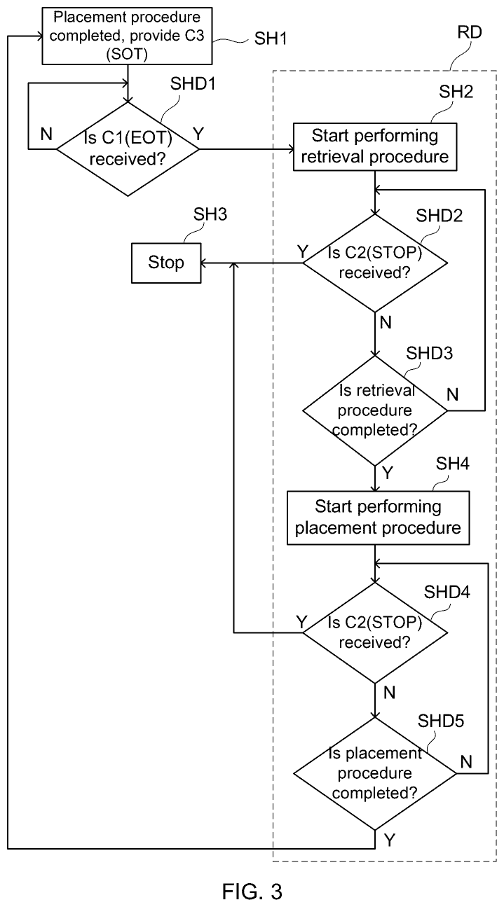

Refer to all of FIG. 1, FIG. 2 and FIG. 3. FIG. 2 shows a schematic diagram of partial processes (the test procedure and a residue test procedure RT) of an integrated circuit test platform with a material overlap prevention function. FIG. 3 shows a schematic diagram of partial processes (the placement procedure and a replacement stage RP) of a class handler of an integrated circuit test system with a material overlap prevention function according to some embodiments.

First of all, when testing begins, the class handler 200 enters an execution step SH1, in which the class handler 200 performs the placement procedure and provides the third command C3 (SOT) to the integrated circuit test platform 100. After the class handler 200 provides the third command C3 (SOT), a determination step SHD1 is performed to wait for the first command C1 (EOT) provided by the integrated circuit test platform 100.

The integrated circuit test platform 100 enters the determination step STD1 after testing begins, so as to determine whether the third command C3 (SOT) provided by the class handler 200 is received. Once the third command C3 (SOT) is received, a step ST1 is performed, in which the test head 120 starts to perform the test procedure (for example, the electrical testing above) on the object under test. When the test procedure is completely performed, the integrated circuit test platform 100 enters an execution step ST2 to provide the first command C1 (EOT) to the class handler 200.

After the class handler 200 receives the first command C1 (EOT) in the determination step SHD1, an execution step SH2 is performed to allow the class handler 200 to start entering operations of the replacement stage RP, in which the class handler 200 first performs the retrieval procedure of the object under test. Moreover, the class handler 200 simultaneously enters a determination step SHD2 to determine whether the second command C2 (STOP) is received. An execution step SH3 is performed if the second command C2 (STOP) is received to cease all operations of the class handler 200; otherwise, a determination step SHD3 is performed if the second command C2 (STOP) is not received (at this point in time, the fetching device 210 of the class handler 200 continues performing the retrieval procedure) to determine whether the retrieval procedure of the object under test is complete. In the determination step SHD3, the determination step SHD2 is again performed if the retrieval procedure of the object under test is not yet complete; otherwise, a step SH4 is performed if the retrieval procedure of the object under test is complete, and the class handler 200 starts to perform the placement procedure of a new object under test.

While performing the placement procedure of the new object under test, the class handler 200 simultaneously enters a determination step SHD4 to continue to determine whether the second command C2 (STOP) is received. An execution step SH3 is performed if the second command C2 (STOP) is received to cease all operations of the class handler 200; otherwise, a determination step SHD5 is performed if the second command C2 (STOP) is not received (at this point in time, the fetching device 210 of the class handler 200 continues performing the placement procedure) to determine whether the placement procedure of the new object under test is complete. In the determination step SHD5, the determination step SHD4 is again performed if the placement procedure of the new object under test is not yet complete; otherwise, the execution step SH1 is iterated if the placement procedure of the new object under test is complete, and the third command C3 (SOT) is provided to the integrated circuit test platform 100. Thus, the class handler 200 has completed the operation of the replacement stage RP.

Details related to the integrated circuit test platform 100 are described below. After providing the first command C1 (EOT) to the class handler 200 in the execution step ST2, the integrated circuit test platform 100 starts to perform the residue test procedure RT. In the residue test procedure RT, the host 110 of the integrated circuit test platform 100 first enters a determination step STD2 to perform one round of electrical measuring by the test head 120. If an electrical value is obtained, it means that there are residues of the object under test, and an execution step ST3 is performed, in which the host 110 provides the second command C2 (STOP) to the class handler 200. If no electrical value is obtained, it means that there are no residues of the object under test or the object under test is temporarily fetched, and a determination step STD3 next is performed to determine whether the number of times of testing has reached a target number. If the number of times of testing has not yet reached the target number, the determination step STD2 is iterated to again perform one round of electrical measuring by the test head 120; otherwise, if the number of times of testing has reached the target number, it means that the residue test procedure RT is complete. When the integrated circuit test platform 100 is later again to carry out testing for a new object under test, the determination step STD1 is again performed.

The determination step STD2 and the determination step STD3 form a test loop, and the number of test loops is correspondingly determined along with setting of the target number of testing. The target number of testing may be determined according to the time of the replacement stage RP and the time needed for each round of testing. For example, in some embodiments, the total time of the replacement stage RP is about 400 ms to 500 ms and the time taken up by each round of electrical measuring in the residue test procedure RT is about 10 ms. Thus, the target number of the electrical measurement within the 400 ms to 500 ms may then be appropriately determined.

In some embodiments, after providing the first command C1 (EOT) to the class handler 200 and before performing the residue test procedure RT, the integrated circuit test platform 100 may undergo a no-operation waiting time; that is, when entering the replacement stage RP after providing the first command C1 (EOT) to the class handler 200, the integrated circuit test platform 100 does not immediately perform the residue test procedure RT but again perform the residue test procedure RT after the waiting time. The reason for the above is due to differences in execution speeds of certain class handlers 200. More specifically, after receiving the first command C1 (EOT), certain class handlers 200 require a period of response time before they can actually perform the retrieval procedure and correctly retrieve the object under test, and if the residue test procedure RT is directly performed within this period of response time, the integrated circuit test platform 100 is caused to immediately issue the second command C2 (STOP). Thus, this waiting time is configured to prevent any test error. Hence, when the residue test procedure RT is set to include a plurality of test loops, the total time taken up by these test loops may be controlled to be less than the total time of the replacement stage RP minus the waiting time above.

In some embodiments, the number of the test loops in the residue test procedure RT may also be set to be in an unlimited number and be continually performed, and the integrated circuit test platform 100 ceases the residue test procedure RT only when the third command C3 (SOT) generated by the class handler 200 is received. In this embodiment, the class handler 200 may also be set to generate the third command C3 (SOT) at a time point before the placement procedure in the replacement stage RP is about to complete. This time point, for example, may be set as an instant when the fetching device 210 of the class handler 200 operates such that a new object under test is about to come into contact with the test head 120 in the placement procedure of the replacement stage RP. For another example, in the placement procedure of the replacement stage RP, when the fetching device 210 of the class handler 200 operates to a predetermined position (for example, a height) and it means that the new object under test is soon to come into contact with the test head 120, it may be set that the class handler 200 generates the third command C3 (SOT) when this position has been reached.

In conclusion, the integrated circuit test platform and the integrated circuit test system with a material overlap prevention function disclosed by the embodiments resolve the issue of possible material overlap caused by a class handler without increasing the total testing time. Moreover, the integrated circuit test platform with a material overlap prevention function also makes up functional shortcomings of certain entry-level class handlers, and at the same time prevents damage of an integrated circuit under test and reduces costs for integrated circuit design providers and test providers.

The present disclosure is illustrated by various aspects and embodiments. However, persons skilled in the art understand that the various aspects and embodiments are illustrative rather than restrictive of the scope of the present disclosure. After perusing this specification, persons skilled in the art may come up with other aspects and embodiments without departing from the scope of the present disclosure. All equivalent variations and replacements of the aspects and the embodiments must fall within the scope of the present disclosure. Therefore, the scope of the protection of rights of the present disclosure shall be defined by the appended claims.

What is claimed is:

1. An integrated circuit test platform with a material overlap prevention function, adapted to collaborate with a class handler to control a placement procedure and a retrieval procedure performed by the class handler, the integrated circuit test platform comprising:
a test head, configured to allow the class handler to place an object under test during the placement procedure, and to retrieve the object under test during the retrieval procedure; and
a host, coupled to the test head and the class handler, configured to perform a test procedure on the object under test by the test head, and for providing a first command to the class handler for the class handler to operate in a replacement stage in which the class handler first performs the retrieval procedure and then performs the placement procedure for replacement with another object under test, the host further for performing a residue test procedure by the test head in the replacement stage and generating a second command for the class handler to cease operation when there are residues of the object under test on the test head.

2. The integrated circuit test platform according to claim 1, wherein during a period of the residue test procedure performed by the host, the class handler is configured to perform only the retrieval procedure of retrieving the object under test from the test head or the placement procedure of placing another object under test.

3. The integrated circuit test platform according to claim 1, wherein the residue test procedure is performed after the replacement stage has operated for a waiting time.

4. The integrated circuit test platform according to claim 3, wherein the residue test procedure comprises a plurality of test loops configured to continuously and repeatedly perform inspection of whether there are residues of the object under test on the test head.

5. The integrated circuit test platform according to claim 4, wherein a total execution time of the test loops is controlled to be less than a replacement time of the replacement stage minus the waiting time.

6. The integrated circuit test platform according to claim 4, wherein the host is controlled to cease the residue test procedure upon receiving a third command generated by the class handler, the third command being generated when the class handler is about to complete the placement procedure of the another object under test.

7. The integrated circuit test platform according to claim 4, wherein each of the test loops is for the host to perform an electrical measurement by the test head.

8. The integrated circuit test platform according to claim 7, wherein the electrical measurement is a measurement of a resistance value.

9. An integrated circuit test system with a material overlap prevention function, comprising:
a class handler, configured to perform a placement procedure or a retrieval procedure; and
an integrated circuit test platform, comprising:
a test head, configured to allow the class handler to place an object under test during the placement procedure and retrieve the object under test during the retrieval procedure; and
a host, coupled to the test head and the class handler, configured to perform a test procedure on the object under test by the test head, and to provide a first command to the class handler for the class handler to operate in a replacement stage, in which the class handler first performs the retrieval procedure and then performs the placement procedure for replacement with another object under test, wherein the host is further for configured to perform a residue test procedure by the test head in the replacement stage and to generate a second command to stop operation of the class handler when residues of the object under test remain on the test head.

10. The integrated circuit test system according to claim 9, wherein during a period of the residue test procedure performed by the host, the class handler is configured to perform only the retrieval procedure of retrieving the object under test from the test head or the placement procedure of placing another object under test.

11. The integrated circuit test system according to claim 9, wherein the residue test procedure is performed after the replacement stage has operated for a waiting time.

12. The integrated circuit test system according to claim 11, wherein the residue test procedure comprises a plurality of test loops configured to continuously and repeatedly perform inspection of whether there are residues of the object under test on the test head.

13. The integrated circuit test system according to claim 12, wherein a total execution time of the test loops is controlled to be less than a replacement time of the replacement stage minus the waiting time.

14. The integrated circuit test system according to claim 12, wherein the host is controlled to cease the residue test procedure upon receiving a third command generated by the class handler, the third command being generated when the class handler is about to complete the placement procedure of the another object under test.

15. The integrated circuit test system according to claim 12, wherein each of the test loops is for the host to perform an electrical measurement by the test head.

16. The integrated circuit test system according to claim 15, wherein the electrical measurement is a measurement of a resistance value.
